(19) United States
(12) Patent Application Publication
(10) Pub. No.: US 2022/0406343 A1
(43) Pub. Date: Dec. 22, 2022

(54) CONTROL CIRCUIT FOR ADJUSTING TIMING OF SENSE AMPLIFIER ENABLE SIGNAL, AND SENSE ENABLE CIRCUIT AND METHOD FOR ENABLING SENSE AMPLIFIER

(71) Applicant: SONIC STAR GLOBAL LIMITED, Tortola (VG)

(72) Inventors: CHIH-CHIEH CHIU, HSINCHU CITY (TW); CHUN-YEN LIN, HUALIEN COUNTY (TW)

(21) Appl. No.: 17/483,450

(22) Filed: Sep. 23, 2021

Related U.S. Application Data
(60) Provisional application No. 63/212,090, filed on Jun. 17, 2021.

(51) Int. Cl. G11C 7/08; G11C 7/12; G11C 7/22

(52) U.S. Cl. CPC G11C 7/08; G11C 7/12; G11C 7/222; H03K 3/0377

(57) ABSTRACT

A sense enable circuit for enabling a sense amplifier is provided. The sense enable circuit includes a signal generator circuit, a group of reference memory cells and a control circuit. The signal generator circuit is configured to generate a sense amplifier enable signal according to a trigger signal. The sense amplifier is enabled by the sense amplifier enable signal to sense data stored in a memory cell. Each reference memory cell is coupled to a reference wordline and a reference bitline. The reference wordline is activated in response to activation of a wordline coupled to the memory cell. The reference memory cell is configured to, in response to activation of the reference wordline, couple a first reference signal to the reference bitline. The control circuit is configured to adjust a signal level of the reference bitline, and generate the trigger signal according to the signal level of the reference bitline.

### PRIORITY CLAIM AND CROSS-REFERENCE

The present application claims priority to U.S. Provisional Patent Application No. 63/212,090, filed on Jun. 17, 2021, which is incorporated by reference herein in its entirety.

### BACKGROUND

The present disclosure relates to memory devices and, more particularly, to a sense enable circuit for activating a sense amplifier in a memory device, and a control circuit and method for adjusting timing of a sense amplifier enable signal.

During a memory read operation, a sense amplifier is utilized to sense data stored in a memory cell and amplify a small voltage swing to a recognizable logic level. For example, the high density of memory cells will result in increased bitline capacitance and a small bitline voltage swing. A sense amplifier can translate a small difference in voltage level between a pair of bitlines to a full logic signal which can be used by other logic circuits. As it takes a period of time for the voltage difference between the pair of bitlines to reach a sufficient level such that the sense amplifier can amplify the voltage difference to a recognizable logic level, a sense amplifier enable signal used for enabling the sense amplifier is usually delayed until a sufficient voltage difference is established. This sufficient voltage difference varies with the process, voltage, and temperature (PVT) corners.

### SUMMARY

The described embodiments provide a sense enable circuit for enabling a sense amplifier, a control circuit for adjusting timing of a sense amplifier enable signal, and a method for operating a sense amplifier.

Some embodiments described herein may include a sense enable circuit for enabling a sense amplifier. The sense enable circuit includes a signal generator circuit, a group of reference memory cells and a control circuit. The signal generator circuit is configured to generate a sense amplifier enable signal according to a trigger signal. The sense amplifier is enabled by the sense amplifier enable signal to amplify a signal representing the data stored in a memory cell. Each reference memory cell is coupled to a reference wordline and a reference bitline. The reference wordline is activated in response to activation of a wordline coupled to the memory cell. In response to activation of the reference wordline, the reference memory cell is configured to couple a first reference signal to the reference bitline. The control circuit, coupled to the reference bitline and the signal generator circuit, is configured to adjust a signal level of the reference bitline, and to generate the trigger signal according to the signal level of the reference bitline.

Some embodiments described herein may include a control circuit for adjusting timing of a sense amplifier enable signal. The sense amplifier enable signal is asserted when a signal level of a trigger signal reaches a predetermined level. The control circuit includes a voltage generator circuit, a capacitive coupling element and a trigger circuit. The voltage generator circuit is configured to provide a supply voltage. The capacitive coupling element, coupled to a reference bitline of a reference memory cell, is configured to capacitively couple a signal level of a reference wordline of the reference memory cell to the reference bitline. A sense amplifier is enabled by the sense amplifier enable signal to sense data stored in a memory cell. The reference wordline is activated in response to activation of a wordline coupled to the memory cell. The reference bitline discharges in response to activation of the reference wordline. The trigger circuit is coupled to the reference bitline and the voltage generator circuit. The trigger circuit is configured to adjust a signal level of the reference bitline according to the supply voltage, and to produce the trigger signal according to the signal level of the reference bitline.

Some embodiments described herein may include a method for operating a sense amplifier. The method includes: discharging a reference bitline of a reference memory cell in response to activation of a wordline coupled to a memory cell, wherein data stored in the memory cell is outputted to the sense amplifier in response to activation of the wordline; capacitively coupling a signal level of a reference wordline of the reference memory cell to the reference bitline, wherein the reference wordline is activated in response to activation of the wordline; adjusting a signal level of the reference bitline to increase a length of time taken for the signal level of the reference bitline to reach a predetermined level; and generating a sense amplifier enable signal according to the signal level of the reference bitline, wherein the sense amplifier enable signal is asserted to enable the sense amplifier when the signal level of the reference bitline reach the predetermined level.

With the use of the proposed control scheme for a sense amplifier, the sense enable circuit can mimic actual characteristics of memory cells such that the enable timing of the sense amplifier can be self-adjusted. The proposed control scheme can strike the balance between performance and yield of memory devices. The yield of memory devices can be kept constant or substantially constant under the influence of PVT variations. Also, the proposed control scheme can reduce test iterations and simplify various EMA settings across the process, operating voltage and operating frequency.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a diagram illustrating an exemplary memory device in accordance with some embodiments of the present disclosure.

FIG. 2 is a block diagram illustrating an exemplary sense enable circuit in accordance with some embodiments of the present disclosure.

FIG. 3 illustrates an implementation of the sense enable circuit shown in FIG. 2 in accordance with some embodiments of the present disclosure.

FIG. 4 illustrates signal waveforms associated with operation of the sense enable circuit shown in FIG. 3 during a read operation in accordance with some embodiments of the present disclosure.

FIG. 5 is a flow chart of an exemplary method for operating a sense amplifier in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, parameter values in the description that follows may vary dependent on a given technology node. As an additional example, parameter values for a given technology node may vary dependent on a given application or operating scenario. Furthermore, the present disclosure may repeat reference numerals and/or letters in the various examples. This repetition is for the purpose of simplicity and clarity and does not in itself dictate a relationship between the various embodiments and/or configurations discussed.

Further, it will be understood that when an element is referred to as being “connected to” or “coupled to” another element, it may be directly connected to or coupled to the other element, or intervening elements may be present. Moreover, as described herein, the terms “assert”, “asserted”, “assertion”, “de-assert”, “de-asserted” and “de-assertion” will be used to avoid confusion when dealing with a mixture of “active high” and “active low” signals. “Assert”, “asserted” and “assertion” are used to indicate that a signal is rendered active, or logically true. “De-assert”, “de-asserted” and “de-assertion” are used to indicate that a signal is rendered inactive, or logically false.

In order to reduce impacts of unexpected manufacturing instability on yield of memory devices, extra margin adjustment (EMA) is utilized to provide extra time for memory access operations. With regard to a memory system which utilizes a dynamic voltage and frequency scaling (DVFS) technique, different EMA settings may be used for memory access operations. For example, when operating at a high voltage or frequency, the memory system may use an EMA setting indicating a relatively small delay value since it would take less time to perform a memory access operation. When operating at a low voltage or frequency, the memory system may use an EMA setting indicating a relatively large delay value since it would take longer time to perform a memory access operation. Delay values stored in the EMA settings are decided based on yield of memory devices after memory built-in self test (MBIST). However, as the EMA is implemented using system-level control units, each memory cell would be applied by a same delay setting rather than a delay setting varying with on-chip variation (OCV), which is induced from semiconductor processes, voltage drops (IR drops) and resistive-capacitive (RC) delays. Multiple test iterations are needed to obtain sufficient EMA settings.

The present disclosure describes exemplary sense enable circuits, each of which can mimic actual characteristics of a memory cell to generate a sense amplifier enable signal used for enabling a sense amplifier. For example, the exemplary sense enable circuit can imitate effects of process variations on the memory cell and/or loadings of a bitline coupled to the memory cell, and accordingly generate the sense amplifier enable signal used for activating the sense amplifier at a suitable time. The exemplary sense enable circuit can keep the yield of memory devices constant or substantially constant under the influence of PVT variations. The present disclosure further describes exemplary control circuits for adjusting timing of a sense amplifier enable signal. For example, the sense amplifier enable signal is asserted when a signal level of a trigger signal reaches a predetermined level. Each of the exemplary control circuits can mimic actual responses of a bitline to process variations and/or electrical loadings, thereby adjusting a length of time taken for the signal level of the trigger signal to reach the predetermined level. The present disclosure further describes exemplary methods for operating sense amplifiers. The proposed control scheme for a sense amplifier can strike the balance between performance and yield of memory devices. Further description is provided below.

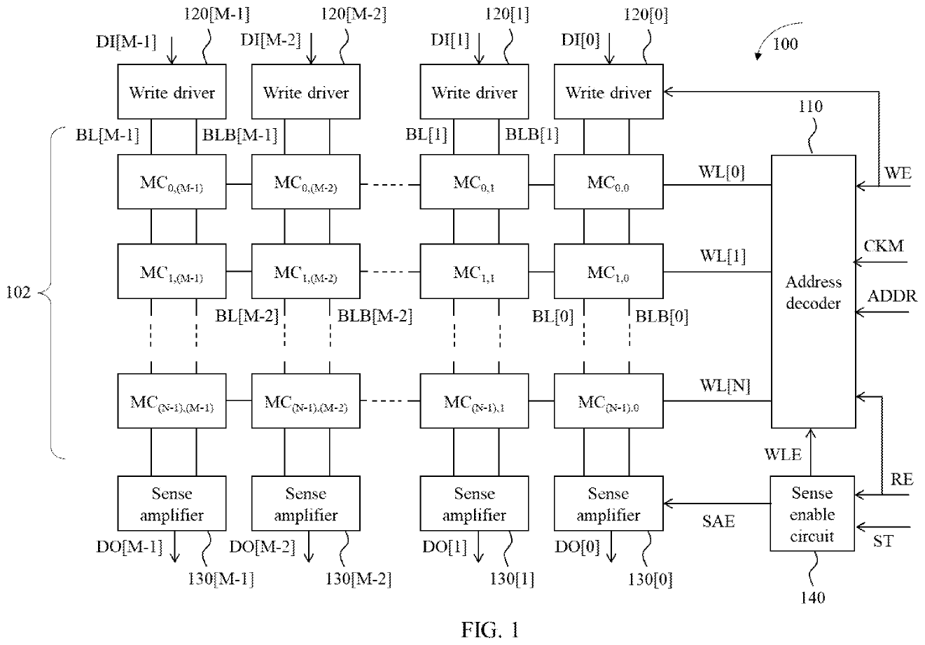

FIG. 1 is a diagram illustrating an exemplary memory device in accordance with some embodiments of the present disclosure. The memory device 100 can be implemented as a static random access memory (SRAM), a dynamic random access memory (DRAM) or other types of memories which utilize senses amplifiers during memory access operations such as write operations or read operations. For example, the memory device 100 can be implemented as an SRAM in a system on chip (SoC) or a mobile SoC. A memory array 102 included in the memory device 100 may have a plurality of memory cells MC_{0,0}-MC_{(N-1),(M-1)} arranged in N rows and M columns, where each of N and M is a positive integer. Each memory cell can be implemented using, but is not limited to, an SRAM memory cell. In the present embodiment, each memory cell is coupled to a wordline and a pair of complementary bitlines. For example, the memory cell MC_{0,0}, is coupled to a wordline WL[0], a bitline BL[0] and a complementary bitline BLB[0].

The memory device 100 may further have an address decoder 110, a plurality of write drivers 120[0]-120[M−1], a plurality of sense amplifiers 130[0]-130[M−1] and a sense enable circuit 140. The address decoder 110, coupled to a plurality of wordlines WL[0]-WL[N−1], is configured to decode an address signal ADDR, and accordingly activate one or more of the wordlines WL[0]-WL[N−1] during a memory access operation. By way of example but not limitation, during a write operation, the address decoder 110 can activate a wordline associated with the address signal ADDR when the clock signal CKM transitions high and a write enable signal WE is asserted. During a read operation, the address decoder 110 can activate a wordline associated with the address signal ADDR when the clock signal CKM transitions high and a read enable signal RE is asserted.

Each of the write drivers 120[0]-120[M−1], coupled to a corresponding pair of bit lines, is configured to drive a data input into a column of memory cells according to an associated write enable signal. For example, when a write enable signal WE is asserted in response to activation of the wordline WL[0], the write driver 120[0] can drive the data input DI[0] into the memory cell MC_{0,0} through the bitlines BL[0] and BLB[0].

Each of the sense amplifiers 130[0]-130[M−1], coupled to a corresponding pair of bit lines, is configured to sense and amplify data on the corresponding pair of bit lines according to a sense amplifier enable signal, and accordingly produce a data output during a read operation. For example, when a sense amplifier enable signal SAE is asserted in response to activation of the wordline WL[0], the sense amplifier 130[0] is enabled to sense and amplify data stored in the memory cell MC_{0,0} through the bitlines BL[0] and BLB[0], and accordingly produce the data output DO[0].

In some embodiments of the present disclosure, the sense enable circuit 140 is configured to generate a wordline enable signal to delay activation of a wordline during a write operation. For example, the write driver 120[0] is activated to drive the data input DI[0] into the memory cell MC_{0,0} in response the activation of the wordline WL[0] from the address decoder 110. The sense enable circuit 140 can output the wordline enable signal WLE to the address decoder 110 to delay activation of the wordline WL[0], thus providing a period of time for the write driver 120[0] to drive the bitlines BL[0] and BLB[0] to respective signal levels capable of representing the data input DI[0].

In the present embodiment, the sense enable circuit 140 is further coupled to each of the sense amplifiers 130[0]-130[M−1], and configured to generate a sense amplifier enable signal associated with each sense amplifier during a read operation. In the present embodiment, the sense enable circuit 140 can be configured to adjust timing of the sense amplifier enable signal by imitating actual characteristics of a memory cell to be read, and accordingly maintain sufficient and stable design margins for an EMA setting.

For example, the memory device 100 utilizes the DVFS technique and has different operating points. The sense enable circuit 140 may receive an EMA setting ST to control operation of the sense amplifier 130[0]. The EMA setting ST can indicate a time delay and an associated operating point, in which the operating point may refer to an operating voltage supplied to the memory device 100 and/or a frequency of the clock signal CKM. The sense enable circuit 140 may mimic actual characteristics of a memory cell to be read, and accordingly tune an elapsed time between the beginning of a read cycle and a time at which an associated sense amplifier enable signal is asserted. To take one example, the wordline WL[0] is activated to read data out of the memory cell MC_{0,0}. In case that the memory cell MC_{0,0} has a slower readout response than expected such that it takes longer to develop a sufficient voltage difference between the bitlines BL[0] and BLB[0], the sense enable circuit 140 can assert the sense amplifier enable signal SAE after a period of time longer than a time delay defined in the EMA setting ST. If the memory cell MC_{0,0} has a faster readout response than expected, the sense enable circuit 140 can assert the sense amplifier enable signal SAE after a period of time shorter than a time delay defined in the EMA setting ST.

As the sense enable circuit 140 can control timing of the sense amplifier enable signal SAE precisely, and maintain sufficient and stable design margins for an EMA setting, the proposed control scheme for a sense amplifier can reduce test iterations and simplify various EMA settings across the process, operating voltage and operating frequency. Also, the proposed control scheme can be applied to various types of integrated circuits including memory devices, such as application processors (AP), to strike the balance between performance and yield of memory devices.

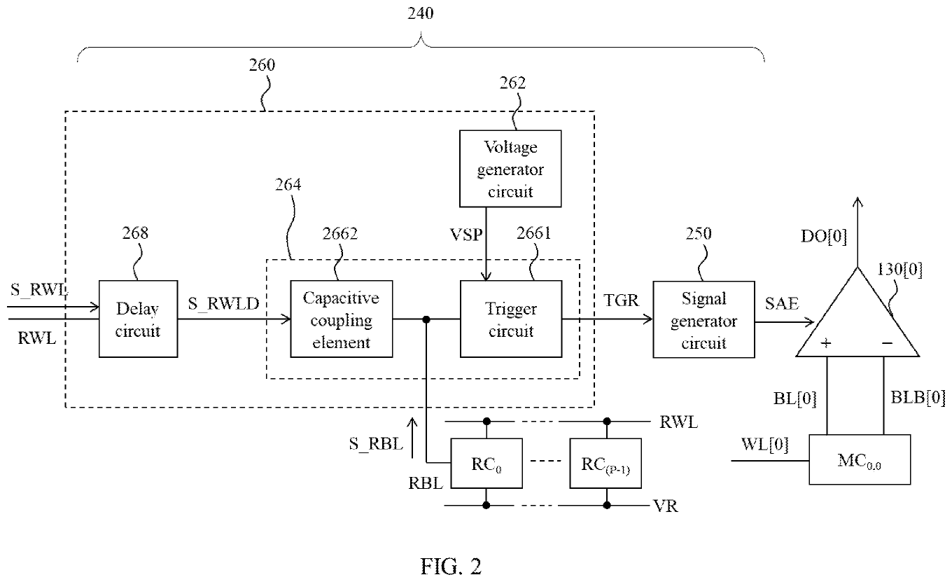

FIG. 2 is a block diagram illustrating an exemplary sense enable circuit in accordance with some embodiments of the present disclosure. The sense enable circuit 240 can represent an embodiment of the sense enable circuit 140 shown in FIG. 1. For illustrative purposes, the operation of the sense enable circuit 240 is described below with reference to the sense amplifier 130[0] shown in FIG. 1. Those skilled will recognize that the sense enable circuit 240 can be used for controlling other sense amplifiers shown in FIG. 1 without departing from the scope of the present disclosure. In addition, the operation of the sense enable circuit 240 is described with reference to the memory cell MC_{0,0} coupled to the sense amplifier 130[0] shown in FIG. 1. In some embodiments, the sense enable circuit 240 can control the sense amplifier 130[0] to sense data stored in other memory cells arranged in a same column without departing from the scope of the present disclosure.

The sense enable circuit 240 includes, but is not limited to, a signal generator circuit 250, a group of reference memory cells RC₀-RC_{(P-1)} and a control circuit 260. P is a positive integer. The signal generator circuit 250, coupled to the sense amplifier 130[0], is configured to generate the sense amplifier enable signal SAE according to a trigger signal TGR. The sense amplifier 130[0] is enabled by the sense amplifier enable signal SAE to sense data stored in the memory cell MC_{0,0}. In the present embodiment, the sense amplifier enable signal SAE can be asserted when a signal level of the trigger signal TGR reaches a predetermined level.

For example, the read enable signal RE is asserted when a read cycle begins. When the read enable signal RE is asserted, a signal level of the sense amplifier enable signal SAE may change in response to a signal level of the trigger signal TGR. Before the signal level of the trigger signal TGR reaches the predetermined level, the sense amplifier enable signal SAE stays de-asserted so the sensor amplifier 130[0] is not activated/enabled. When the signal level of the trigger signal TGR reaches the predetermined level, the sense amplifier enable signal SAE is asserted to allow the sense amplifier 130[0] to sense and amplify data stored in the memory cell MC_{0,0}.

Each cell in the group of reference memory cells RC₀-RC_{(P-1)} is coupled to a reference wordline RWL and a reference bitline RBL. The reference wordline RWL can be activated in response to activation of the wordline WL[0]. Each reference memory cell can be configured to, in response to activation of the reference wordline RWL, couple a reference signal VR to the reference bitline RBL. As the reference wordline RWL and the wordline WL[0] can be activated/de-activated at the same or substantially the same time, the reference wordline RWL can be regarded as a replica of the wordline WL[0], and each reference memory cell can be regarded as a replica of the memory cell MC_{0,0}. In addition, the reference bitline RBL coupled to each reference memory cell can be regarded as a replica of the bitline BL[0]/BLB[0]. For example, the reference signal VR may correspond to a logic low level such as a ground voltage. The reference bitline RBL can be regarded as a replica of one of the bitlines BL[0] and BLB[0], which becomes the logic low level during a read operation. As another example, the reference signal VR may correspond to a logic high level such as a ground voltage. The reference bitline RBL can be regarded as a replica of one of the bitlines BL[0] and BLB[0], which turns into the logic high level during a read operation.

The control circuit 260, coupled to the reference bitline RBL and the signal generator circuit 250, is configured to reshape a signal S_RBL on the reference bitline RBL, and generate the trigger signal TGR according to a signal level of the reference bitline RBL. The control circuit 260 can adjust the signal level of the reference bitline RBL to simulate the behavior of the bitline BL[0]/BLB[0]. The signal level of the trigger signal TGR, varying with the signal level of the reference bitline RBL, reflects the behavior of the bitline BL[0]/BLB[0] accordingly. When the signal level of the trigger signal TGR reaches the predetermined level, this may mean that a voltage difference between the bitlines BL[0] and BLB[0] reaches a sufficient level. The sense amplifier enable signal SAE is asserted when the signal level of the trigger signal TGR reaches the predetermined level. In the example of FIG. 2, the sense amplifier 130[0] can be activated at a time when a sufficient voltage difference between the bitlines BL[0] and BLB[0] is established.

In some embodiments, the control circuit 260 can be configured to adjust a length of time taken for the signal level of the trigger signal TGR to reach the predetermined level by reshaping the signal S_RBL on the reference bitline RBL. For example, the memory cell MC_{0,0} may have a slow readout response such that a period of time taken for a voltage difference between the bitlines BL[0] and BLB[0] to reach a sufficient level is longer than a time delay indicated in an EMA setting. The control circuit 260 can react to the slower response by increasing the length of time taken for the signal level of the trigger signal TGR to reach the predetermined level. As another example, the memory cell MC_{0,0} may have a fast readout response such that a period of time taken for a voltage difference between the bitlines BL[0] and BLB[0] to reach a sufficient level is shorter than a time delay indicated in an EMA setting. The control circuit 260 can react to the faster response by decreasing the length of time taken for the signal level of the trigger signal TGR to reach the predetermined level.

In some embodiments, the trigger signal TGR reaches the predetermined level following the signal S_RBL on the reference bitline RBL. For example, the control circuit 260 can apply an additional delay to the signal S_RBL on the reference bitline RBL to produce the trigger signal TGR, in which the additional delay reflects the effects of process variations and/or voltage drops upon the memory cell MC_{0,0}.

With the use of the group of reference memory cells RC₀-RC_{(P-1)}, the reference wordline RWL and the reference bitline RBL, the control circuit 260 can simulate the effects of process variations on the memory cell MC_{0,0} and/or loadings of the bitline BL[0]/BLB[0], thereby generating the trigger signal TGR which may reflect the effects of RC delays, node biasing and/or a power supply source upon the memory cell MC_{0,0}. By adaptively tuning the signal level of the trigger signal TGR, the control circuit 260 carries out self-adjustment of the sense amplifier enable signal SAE.

In the present embodiment, the control circuit 260 may include, but is not limited to, a voltage generator circuit 262, a tuning circuit 264 and a delay circuit 268. The voltage generator circuit 262 is configured to provide a supply voltage VSP. The voltage generator circuit 262 may be implemented using a voltage modulator, a voltage regulator, a clamping diode, a voltage divider, or other types of voltage generators. In addition, the voltage generator circuit 262 may be an internal or external voltage source. For example, the voltage generator circuit 262 and the memory array 102 shown in FIG. 1 can be implemented in a same chip. The voltage generator circuit 262 can serve as an internal voltage source. As another example, the voltage generator circuit 262 and the memory array 102 shown in FIG. 1 can be implemented in separate chips. The voltage generator circuit 262 can serve as an external voltage source.

The tuning circuit 264, coupled to the voltage generator circuit 262 and the reference bitline RBL, is configured to adjust the signal level of the trigger signal TGR according to the supply voltage VSP and the signal level of the reference bitline RBL. By way of example but not limitation, the tuning circuit 264 may include a trigger circuit 2661 and a capacitive coupling element 2662. The trigger circuit 2661 is coupled to the reference bitline RBL and the voltage generator circuit 262. The trigger circuit 2661 can be configured to adjust the signal level of the reference bitline RBL according to the supply voltage VSP, and to produce the trigger signal TGR according to the signal level of the reference bitline RBL. For example, the trigger circuit 2661 can apply a time delay to the signal S_RBL on the reference bitline RBL to produce the trigger signal TGR, in which the time delay can vary with a voltage level of the supply voltage VSP. The trigger signal TGR may be regarded as a delayed version of the signal S_RBL on the reference bitline RBL. In the example of FIG. 2, when the voltage level of the supply voltage VSP increases, the trigger circuit 2661 can be configured to slow a rate of change of a signal level of the signal S_RBL.

The capacitive coupling element 2662, coupled to the reference bitline RBL, is configured to capacitively couple a signal level of the reference wordline RWL to the reference bitline RBL, thereby reshaping the signal S_RBL on the reference bitline RBL. The delay circuit 268, coupled between the reference wordline RWL and the capacitive coupling element 2662, is configured to delay a signal S_RWL applied to the reference wordline RWL to generate the delayed signal S_RWLD.

In the present embodiment, the capacitive coupling element 2662 is configured to capacitively couple a delayed version of a signal S_RWL on the reference wordline RWL, i.e. the delayed signal S_RWLD, to the reference wordline RBL. In this way, capacitive loading can be adaptively applied to the reference wordline RWL and the reference bitline RBL. However, this is not intended to limit the scope of the present disclosure. In some embodiments, the delay circuit 268 may be optional. The capacitive coupling element 2662 may directly receive the signal S_RWL on the reference wordline RWL to thereby capacitively couple the reference wordline RWL to the reference wordline RBL. Such alternatives also fall within the scope of the present disclosure.

Note that the delay circuit 268 may reflect at least the effects of RC delay on the memory cell MC_{0,0}. The capacitive coupling element 2662 may reflect at least the effects of process variation on the memory cell MC_{0,0}. The trigger circuit 2661 may reflect at least the effects of process variation and node biasing on the memory cell MC_{0,0}. The voltage generator circuit 262 may reflect at least the effects of a power supply source on the memory cell MC_{0,0}.

To facilitate understanding of the present disclosure, an exemplary implementation of the architecture shown in FIG. 2 is given below for further description of the proposed control scheme for a sense amplifier. However, this is provided for illustrative purposes, and is not intended to limit the scope of the present disclosure. As long as a sense enable circuit can imitate actual characteristics of a memory cell to implement a self-adjustment of a sense amplifier enable signal, associated modifications and alternatives are contemplated to fall within the scope of the present disclosure.

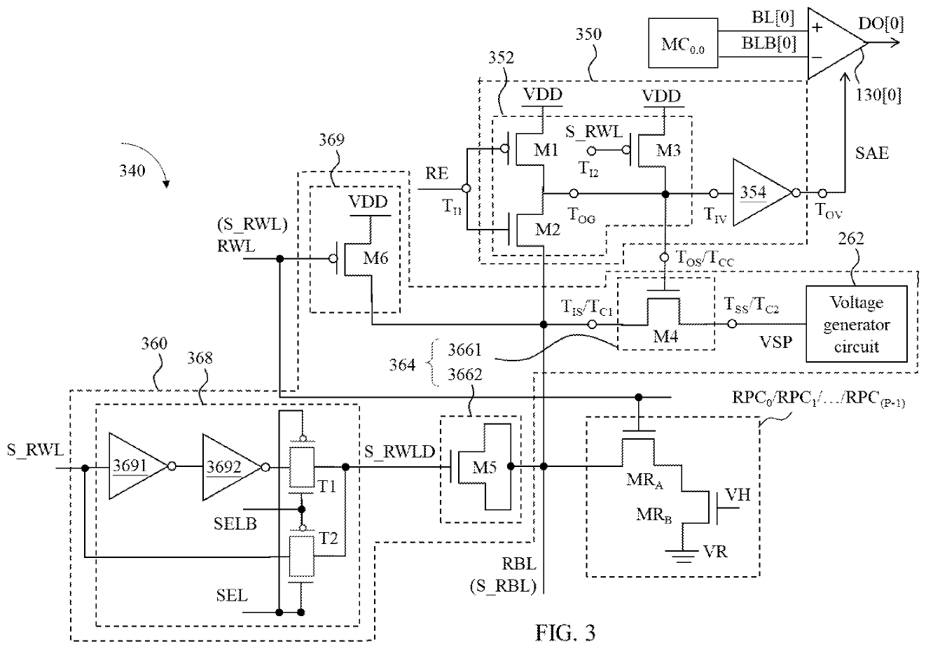

FIG. 3 illustrates an implementation of the sense enable circuit 240 shown in FIG. 2 in accordance with some embodiments of the present disclosure. The sense enable circuit 340 includes a signal generator circuit 350, a group of reference memory cells RPC₀-RPC_{(P-1)} and a control circuit 360, which can represent embodiments of the signal generator circuit 250, the group of reference memory cells RC₀-RC_{(P-1)} and the control circuit 260 shown in FIG. 2, respectively.

The signal generator circuit 350 includes, but is not limited to, a NAND gate 352 and an inverter 354. The NAND gate 352 is coupled between a reference signal VDD and the reference bitline RBL, in which the reference signal VDD is different from the reference signal VR coupled to the group of reference memory cells RPC₀-RPC_{(P-1)}. The input terminals T₁₁ and T₁₂ of the NAND gate 352 are coupled to the read enable signal RE and the reference wordline RBL, respectively. An output terminal T_{OG} of the NAND gate 352 is coupled to the trigger signal TGR. In the present embodiment, the NAND gate 352 may be implemented using a plurality of transistors M1-M3. Each of the transistors M1 and M3 can be implemented using an n-channel transistor, and the transistor M2 can be implemented using a p-channel transistor.

The inverter 354 includes an input terminal T_{IV} and an output terminal T_{OV}. The input terminal T_{IV} is coupled to the output terminal T_{OG} to receive the trigger signal TGR. The output terminal T_{OV} is arranged to output the sense amplifier enable signal SAE. When a signal level at the input terminal T_{IV}, i.e. the signal level of the trigger signal TGR, reaches a predetermined level, a level transition would occur in the sense amplifier enable signal SAE.

Each cell in the group of reference memory cells RPC₀-RPC_{(P-1)} can be implemented using a plurality of transistors MR_{A} and MR_{B} connected in series between the reference bitline RBL and the reference signal VR, which is implemented using a ground voltage in the present embodiment. A control terminal of the transistor MR_{A} is coupled to the reference wordline RWL, and a control terminal of the transistor MR_{B} is tied to a high voltage VH such as the reference signal VDD. As a result, the reference bitline RBL can discharge in response to activation of the reference wordline RWL.

The control circuit 360 may include the voltage generator circuit 262 shown in FIG. 2, a tuning circuit 364 and a delay circuit 368. The tuning circuit 364 and the delay circuit 368 can represent embodiments of the tuning circuit 264 and the delay circuit 268 shown in FIG. 2, respectively. The tuning circuit 364 include a Schmitt trigger 3661 and a capacitive coupling element 3662, which represent embodiments of the trigger circuit 2661 and the capacitive coupling element 2662, respectively.

The Schmitt trigger 3661 includes a supply terminal T_{SS}, an input terminal T_{IS} and an output terminal T_{OS}. The supply terminal T_{SS} is coupled to the supply voltage VSP. The input terminal T_{IS} is coupled to the reference bitline RBL. The output terminal T_{OS} is coupled to the signal generator circuit 262, and arranged to output the trigger signal TGR. The Schmitt trigger 3661 can enable its input signal to adapt a trigger point to below half of the supply voltage VSP, and accordingly adjust a length of time taken for the trigger signal TGR to reach the predetermined level. By way of example but not limitation, the Schmitt trigger 3661 can be arranged to include a transistor M4. A control terminal T_{CC}, a connection terminal T_{C1} and a connection terminal T_{C2} of the transistor M4 can serve as the output terminal T_{OS}, the input terminal T_{IS} and the supply terminal T_{SS}, respectively. The signal level of the trigger signal TGR would vary with a threshold voltage of the transistor M4 and a voltage level of the supply voltage VSP.

The capacitive coupling element 3662 is implemented using a transistor M5 whose drain, source and bulk are connected together to form a MOS (metal-oxide-semiconductor) capacitor. The gate of the transistor M5 is arranged to receive the delayed signal S_RWLD.

The delay circuit 368 includes, but is not limited to, a plurality of inverters 3691 and 3692, and a plurality of transmission gates T1 and T2. The delay circuit 368 can selectively provide a delay path formed by the inverters 3691 and 3692 connected in series according to a plurality of select signals SEL and SELB complementary to each other. When the transmission gate T1 is turned on, the transmission gate T2 is turned off, and the delay circuit 368 is configured to transmit the signal S_RWL through the inverter 3691, the inverter 3692 and the transmission gate T1 to thereby generate the delayed signal S_RWLD. When the transmission gate T1 is turned off, the transmission gate T2 is turned on to output the signal S_RWL.

In the present embodiment, the control circuit 360 further includes a switch 369 coupled to the reference wordline RBL. The switch 369 is configured to couple the reference signal VDD to the reference bitline RBL before the reference wordline RWL is activated, and uncouple the reference signal VDD from the reference bitline RBL when the reference wordline RWL is activated. In the present embodiment, the switch 369 can be implemented using a transistor M6. Also, the switch 369 serve as a precharge circuit, which is configured to precharge the reference bitline RBL to a voltage level of the reference signal VDD.

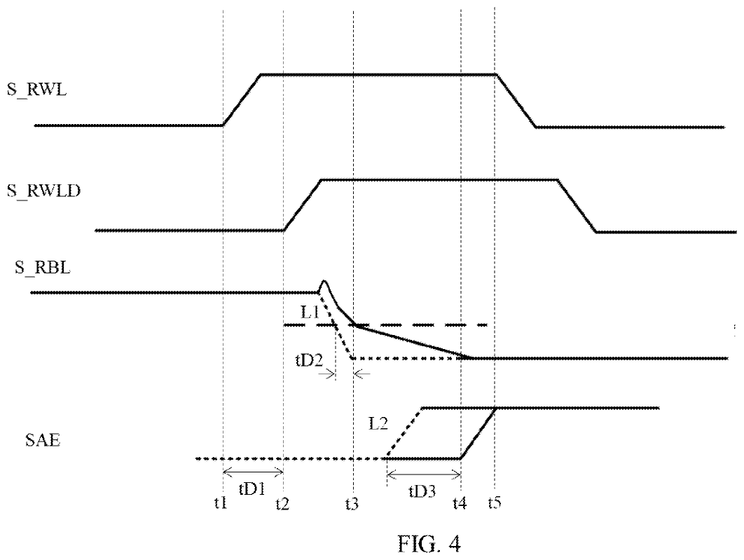

FIG. 4 illustrates signal waveforms associated with operation of the sense enable circuit 340 shown in FIG. 3 during a read operation in accordance with some embodiments of the present disclosure. Referring to FIG. 4 and also to FIG. 3, prior to time t1, the read enable signal RE is asserted, e.g. at a logic high level. As the signal S_RWL applied to the reference wordline RWL is at a logic low level, the reference bitline RBL can be precharged to the voltage level of the reference signal VDD. In other words, the signal S_RBL on the reference bitline RBL is at a logic high level.

At time t1, a low to high transition of the signal S_RWL begins in response to activation of the wordline RWL. As the transmission gate T1 is turned on according to the select signals SEL and SELB, the delay circuit 368 can apply a time delay tD to the signal S_RWL, and accordingly produce the delayed signal S_RWLD. After the time delay tD1 has elapsed, a low to high transition of the signal S_RWLD begins at time t2. The time delay tD1 may reflect the effect of RC delays on the memory cell MC_{0,0}.

Between time t2 and time t3, the capacitive coupling element 3662 can capacitively couple the signal S_RWLD to the reference bitline RBL to make the signal S_RBL ramp down more slowly. After time t3, the Schmitt trigger 3661 can further slow down the falling transition of the signal S_RBL according to the supply voltage VSP, and thus produce the trigger signal TGR.

Still referring to FIG. 4, the dashed line L1 represents signal level changes of the signal S_RBL produced in a case that the Schmitt trigger 3661 and the capacitive coupling element 3662 are omitted from the control circuit 360. The time delay tD2 may vary with coupling capacitance of the capacitive coupling element 3662, and reflect the effects of process variations and loadings of the bitline BL[0]/BLB[0]. As a result, the response of the reference bitline RBL to the capacitive coupling of the signal S_RWLD is close to the actual behavior of the bitline BL[0]/BLB[0]. In addition, the coupling capacitance of the capacitive coupling element 3662 can produce an additional delay against a fast process. The sufficient yield of memory devices can be assured.

Further, a length of time taken for the signal S_RBL to reach a trigger point may vary with the threshold voltage of the transistor M4 and the voltage level of the supply voltage VSP, in which the sense amplifier enable signal SAE can be asserted when the signal S_RBL reaches the trigger point. Consider a case that the memory cell MC_{0,0} has a much slower readout response. The Schmitt trigger 3661 may adapt the trigger point to a level below half of the supply voltage VSP, and the sense amplifier enable signal SAE can be asserted when the signal level of reference bitline RBL reaches the trigger point. Additionally, the voltage generator circuit 262 can delay the enable timing of the sense amplifier 130[0] by increasing the voltage level of the supply voltage VSP. For example, when the voltage level of the supply voltage VSP increases, a rate of change of the signal level of the reference bitline RBL decreases.

Between time t4 and time t5, a low to high transition occurs in the sense amplifier enable signal SAE because the signal level of the trigger signal TGR reaches a predetermined level. The dashed line L2 represents signal level changes of the sense amplifier enable signal SAE produced in a case that the Schmitt trigger 3661 and the capacitive coupling element 3662 are omitted from the control circuit 360. With the use of the Schmitt trigger 3661 and the capacitive coupling element 3662, the control circuit 360 can delay assertion of the sense amplifier enable signal SAE by the time delay tD3.

With the use of the control circuit 360, the signal S_RBL on the reference bitline RBL can be shaped and reshaped, thereby tuning a trigger time point at which the sense amplifier enable signal SAE is asserted. The yield of memory devices can be kept constant or substantially constant under the influence of PVT variations.

The circuit structures described above are provided for illustrative purposes, and are not intended to limit the scope of the present disclosure. In some embodiments, the signal generator 350 can be implemented using other circuit structures, capable of asserting the sense amplifier enable signal SAE according to the trigger signal TGR during a read operation, without departing from the scope of the present disclosure. In some embodiments, the delay circuit 368 may implemented using various delay circuits, such as stacked gate buffers, a combination of feedback loops, or other types of delay circuits. In some embodiments, the capacitive coupling element 3662 may implemented using metal-insulator-metal (MIM) capacitors, parasitic layout layers including poly layers and metal layers, or other types of capacitive coupling elements.

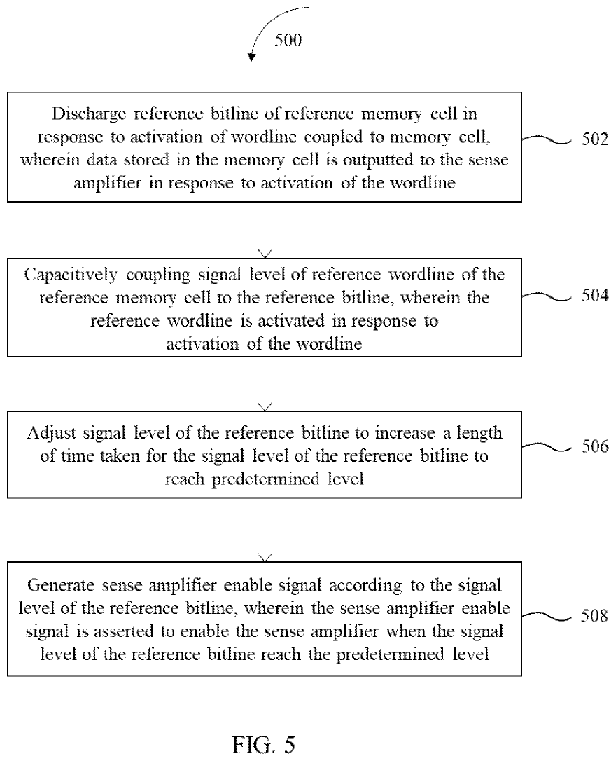

FIG. 5 is a flow chart of an exemplary method for operating a sense amplifier in accordance with some embodiments of the present disclosure. For illustrative purposes, the method 500 is described below with reference to the sense enable circuit 340 shown in FIG. 3. Note that the method 500 can be employed in the sense enable circuit 140 shown in FIG. 1 or the sense enable circuit 240 shown in FIG. 2 without departing from the scope of the present disclosure. Additionally, in some embodiments, other operations in the method 500 can be performed. In some other embodiments, operations of the method 500 can be performed in a different order and/or vary

At operation 502, a reference bitline of a reference memory cell is discharged in response to activation of a wordline coupled to a memory cell, and the data stored in the memory cell is outputted to the sense amplifier in response to activation of the wordline. For example, when the reference wordline RWL is activated in response to activation of the wordline WL, each cell in the group of reference memory cells RPC₀-RPC_{(P-1)} is configured to couple the reference bitline RBL to the reference signal VR, such as a ground voltage, to thereby discharge the reference bitline RBL. The data stored in the memory cell MC_{0,0} is outputted to the sense amplifier 130[0] through the bitlines BL[0] and BLB[0].

At operation 504, a signal level of a reference wordline of the reference memory cell is capacitively coupled to the reference bitline, in which the reference wordline is activated in response to activation of the wordline. For example, the capacitive coupling element 3662 can capacitively couple the delayed signal S_RWLD to the reference bitline RBL.

At operation 506, a signal level of the reference bitline is adjusted to increase a length of time taken for the signal level of the reference bitline to reach a predetermined level. For example, the tuning circuit 364 can slow down the falling transition of the signal S_RBL to increase a length of time taken for the signal S_RBL to reach a predetermined level.

At operation 508, a sense amplifier enable signal is generated according to the signal level of the reference bitline, and the sense amplifier enable signal is asserted to enable the sense amplifier when the signal level of the reference bitline reach the predetermined level. For example, the control circuit 360 can generate the trigger signal TGR according to the signal level of the reference bitline RBL. When the signal S_RBL reaches the predetermined level such that the signal level of the trigger signal TGR can trigger a level transition of the sense amplifier enable signal SAE, the signal generator 350 can assert the sense amplifier enable signal SAE accordingly.

In some embodiments, before the reference wordline RWL is activated, the switch 369 can couple the reference signal VDD to the reference bitline RBL to precharge the reference bitline RBL. When the reference wordline RWL is activated, the switch 369 can uncouple the reference signal VDD from the reference bitline RBL to allow the discharging of the reference bitline RBL.

As those skilled in the art can appreciate the operation of the method 500 after reading the above paragraphs directed to FIG. 1 through FIG. 4, further description is omitted here for brevity.

With the use of the proposed control scheme for a sense amplifier, the sense enable circuit can mimic actual characteristics of memory cells such that the enable timing of the sense amplifier can be self-adjusted. The proposed control scheme can strike the balance between performance and yield of memory devices. The yield of memory devices can be kept constant or substantially constant under the influence of PVT variations. Also, the proposed control scheme can reduce test iterations and simplify various EMA settings across the process, operating voltage and operating frequency.

The foregoing outlined features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A sense enable circuit for enabling a sense amplifier, the sense enable circuit comprising:
a signal generator circuit, configured to generate a sense amplifier enable signal according to a trigger signal, wherein the sense amplifier is enabled by the sense amplifier enable signal to sense data stored in a memory cell;
a group of reference memory cells, each reference memory cell being coupled to a reference wordline and a reference bitline, the reference wordline being activated in response to activation of a wordline coupled to the memory cell, wherein the reference memory cell is configured to, in response to activation of the reference wordline, couple a first reference signal to the reference bitline; and
a control circuit, coupled to the reference bitline and the signal generator circuit, the control circuit being configured to adjust a signal level of the reference bitline, and generate the trigger signal according to the signal level of the reference bitline.

2. The sense enable circuit of claim 1, wherein the sense amplifier enable signal is asserted when a signal level of the trigger signal reaches a predetermined level;
the control circuit is configured to adjust a length of time taken for the signal level of the trigger signal to reach the predetermined level by adjusting the signal level of the reference bitline.

3. The sense enable circuit of claim 2, wherein the trigger signal reaches the predetermined level following a signal on the reference bitline.

4. The sense enable circuit of claim 1, wherein the control circuit comprises:
a voltage generator circuit, configured to provide a supply voltage; and
a Schmitt trigger, having a supply terminal, an input terminal and an output terminal, wherein the supply terminal is coupled to the supply voltage, the input terminal is coupled to the reference bitline, and the output terminal is coupled to the signal generator circuit; the Schmitt trigger is configured to generate the trigger signal at the output terminal.

5. The sense enable circuit of claim 4, wherein the Schmitt trigger comprises a transistor; wherein a control terminal, a first connection terminal and a second connection terminal of the transistor serve as the output terminal, the input terminal and the supply terminal, respectively.

6. The sense enable circuit of claim 4, wherein the Schmitt trigger is configured to slow a rate of change of the signal level of the reference bitline when a voltage level of the supply voltage increases.

7. The sense enable circuit of claim 4, wherein the control circuit further comprises:
a capacitive coupling element, coupled to the reference bitline, the capacitive coupling element being configured to capacitively couple a signal level of the reference wordline to the reference bitline.

8. The sense enable circuit of claim 7, wherein the control circuit further comprises:
a delay circuit, coupled between the reference wordline and the capacitive coupling element, the delay circuit being configured to delay a signal applied to the reference wordline to generate a delayed signal, wherein the capacitive coupling element is configured to capacitively couple the delayed signal to the reference bitline.

9. The sense enable circuit of claim 1, the control circuit further comprises:
a switch coupled to the reference wordline, wherein the switch is configured to couple a second reference signal, which is different from the first reference signal, to the reference bitline before the reference wordline is activated, and uncouple the second reference signal from the reference bitline when the reference wordline is activated.

10. The sense enable circuit of claim 1, wherein the signal generator circuit comprises:
a NAND gate coupled between a second reference signal and the reference bitline, the second reference signal being different from the first reference signal, wherein a first input terminal and a second input terminal of the NAND gate are coupled to a read enable signal and the reference wordline, respectively; an output terminal of the NAND gate is coupled to the trigger signal; and
an inverter, wherein an input terminal of the inverter is coupled to the output terminal of the NAND gate to receive the trigger signal, and an output terminal of the inverter is arranged to output the sense amplifier enable signal.

11. A control circuit for adjusting timing of a sense amplifier enable signal, the sense amplifier enable signal being asserted when a signal level of a trigger signal reaches a predetermined level, the control circuit comprising:
a voltage generator circuit, configured to provide a supply voltage;
a capacitive coupling element, coupled to a reference bitline of a reference memory cell, the capacitive coupling element being configured to capacitively couple a signal level of a reference wordline of the reference memory cell to the reference bitline, wherein a sense amplifier is enabled by the sense amplifier enable signal to sense data stored in a memory cell, the reference wordline is activated in response to activation of a wordline coupled to the memory cell, and the reference bitline discharges in response to activation of the reference wordline; and
a trigger circuit, coupled to the reference bitline and the voltage generator circuit, the trigger circuit being configured to adjust a signal level of the reference bitline according to the supply voltage, and to produce the trigger signal according to the signal level of the reference bitline.

12. The control circuit of claim 11, wherein the trigger signal reaches the predetermined level following a signal on the reference bitline.

13. The control circuit of claim 11, wherein the trigger circuit is a Schmitt trigger having a supply terminal, an input terminal and an output terminal; the supply terminal is coupled to the supply voltage, the input terminal is coupled to the reference bitline, and the output terminal is arranged to output the trigger signal.

14. The control circuit of claim 13, wherein the Schmitt trigger comprises a transistor; wherein a control terminal, a first connection terminal and a second connection terminal of the transistor serve as the output terminal, the input terminal and the supply terminal, respectively.

15. The control circuit of claim 11, wherein when a voltage level of the supply voltage increases, the trigger circuit is configured to slow a rate of change of the signal level of the reference bitline.

16. The control circuit of claim 11, further comprising:
a delay circuit, coupled between the reference wordline and the capacitive coupling element, the delay circuit being configured to delay a signal applied to the reference wordline to generate a delayed signal, wherein the capacitive coupling element is configured to capacitively couple the delayed signal to the reference bitline.

17. The control circuit of claim 11, further comprising:
a switch coupled to the reference wordline, wherein the switch is configured to couple a reference signal to the reference bitline before the reference wordline is activated, and uncouple the reference signal from the reference bitline when the reference wordline is activated.

18. A method for operating a sense amplifier, comprising:
discharging a reference bitline of a reference memory cell in response to activation of a wordline coupled to a memory cell, wherein data stored in the memory cell is outputted to the sense amplifier in response to activation of the wordline;
capacitively coupling a signal level of a reference wordline of the reference memory cell to the reference bitline, wherein the reference wordline is activated in response to activation of the wordline;
adjusting a signal level of the reference bitline to increase a length of time taken for the signal level of the reference bitline to reach a predetermined level; and
generating a sense amplifier enable signal according to the signal level of the reference bitline, wherein the sense amplifier enable signal is asserted to enable the sense amplifier when the signal level of the reference bitline reach the predetermined level.

19. The method of claim 18, wherein the step of capacitively coupling the signal level of the reference wordline to the reference bitline comprises:
delaying a signal applied to the reference wordline to generate a delayed signal; and
coupling the delayed signal to the reference bitline, thereby capacitively coupling the signal level of the reference wordline to the reference bitline.

20. The method of claim 18, further comprising:
before the reference wordline is activated, coupling a reference signal to the reference bitline; and
when the reference wordline is activated, uncoupling the reference signal from the reference bitline.
